(19) United States
(12) Patent Application Publication
(10) Pub. No.: US 2026/0231574 A1
(43) Pub. Date: Aug. 6, 2026

(54) LIGHT-EMITTING DEVICE AND LIGHT-EMITTING MODULE

(71) Applicant: Nichia Corporation, Anan-shi (JP)

(72) Inventors: Seitaro AKAGAWA, Komatsushima-shi (JP); Yuichi YAMADA, Itano-gun (JP); Tomonori OZAKI, Anan-shi (JP); Toshiaki MORIWAKI, Itano-gun (JP); Yasumasa YAMAMOTO, Myozai-gun (JP)

(21) Appl. No.: 19/462,215

(22) Filed: Jan. 28, 2026

(30) Foreign Application Priority Data
Feb. 4, 2025 (JP) 2025-017115

(51) Int. Cl. H10H 20/857; H10H 20/84; H10H 20/85

(52) U.S. Cl. CPC H10H 20/857; H10H 20/84; H10H 20/8508

(57) ABSTRACT

A light-emitting device includes a support body including a first through hole and a second through hole, a light source including a first electrode and a second electrode, a first conductive member including a first part within the first through hole and electrically connected to the first electrode, a second conductive member including a second part within the second through hole and electrically connected to the second electrode, and an insulating member overlapping the first part and the second part in a view from a side of a second surface of the support body opposite to a side on which the light source is mounted. A shortest distance from an exposed region of the first conductive member to an exposed region of the second conductive member is greater than a shortest distance from the first through hole to the second through hole.

### CROSS-REFERENCE TO RELATED APPLICATION

This application claims priority to Japanese Patent Application No. 2025-017115 filed on Feb. 4, 2025, the disclosure of which is hereby incorporated by reference in its entirety.

### BACKGROUND

### Field of the Invention

The present disclosure relates to a light-emitting device and a light-emitting module.

### Description of Related Art

Japanese Unexamined Patent Application Publication No. 2017-188589 discloses a light-emitting device that includes a plurality of light-emitting elements, a substrate having a plurality of through vias, and an insulating film covering a rear surface of the substrate.

### SUMMARY OF THE INVENTION

There is a demand for light-emitting devices with improved reliability. An object of certain embodiments of the present invention is to provide a light-emitting device and a light-emitting module with high reliability.

A light-emitting device according to an embodiment of the present invention includes a support body having a first through hole and a second through hole that extend from a first surface to a second surface opposite to the first surface, a light source mounted on the support body on a side of the first surface and including a first electrode and a second electrode, a first conductive member electrically connected to the first electrode, the first conductive member including a first part within the first through hole and a second part on a side of the second surface, the second part being continuous with the first part, a second conductive member electrically connected to the second electrode, the second conductive member including a third part within the second through hole and a fourth part on the side of the second surface, the fourth part being continuous with the third part, and an insulating member disposed on the side of the second surface. The insulating member overlaps at least a portion of the first part and at least a portion of the third part in a view from the side of the second surface. A shortest distance from an exposed region of the first conductive member that is exposed to the side of the second surface and uncovered by the insulating member to an exposed region of the second conductive member that is exposed to the side of the second surface and uncovered by the insulating member is greater than a shortest distance from the first through hole to the second through hole.

A light-emitting module according to an embodiment of the present invention includes: the light-emitting device described above; a wiring substrate including a first wiring member and a second wiring member; a first conductor electrically connecting the first conductive member to the first wiring member; and a second conductor electrically connecting the second conductive member to the second wiring member.

According to an embodiment of the present invention, the reliability of the light-emitting device and light-emitting module can be improved.

### BRIEF DESCRIPTION OF THE DRAWINGS

FIG. 1 schematically illustrates a top view of a light-emitting device according to a first embodiment.

FIG. 2 schematically illustrates an enlarged view of region II in FIG. 1.

FIG. 3 schematically illustrates an enlarged view of region III in FIG. 2.

FIG. 4 schematically illustrates a cross-sectional view of the light-emitting device taken along line IV-IV of FIG. 3.

FIG. 5 schematically illustrates a cross-sectional view of a light source according to the first embodiment.

FIG. 6 schematically illustrates a bottom view of the light-emitting device according to the first embodiment to show a positional relationship of a first through hole, a second through hole, a first conductive member, a second conductive member, and an insulating member in the light-emitting device according to the first embodiment.

FIG. 7 schematically illustrates a bottom view of a light-emitting device according to Modified Example 1 of the first embodiment to show a positional relationship of a first through hole, a second through hole, a first conductive member, a second conductive member, and an insulating member in the light-emitting device according to Modified Example 1 of the first embodiment.

FIG. 8 schematically illustrates a bottom view of a light-emitting device according to Modified Example 2 of the first embodiment to show a positional relationship of a first through hole, a second through hole, a first conductive member, a second conductive member, and an insulating member in the light-emitting device according to Modified Example 2 of the first embodiment.

FIG. 9 schematically illustrates a cross-sectional view of a light-emitting device according to Modified Example 3 of the first embodiment.

FIG. 10 schematically illustrates a cross-sectional view of a light-emitting module according to a second embodiment.

FIG. 11 schematically illustrates a bottom view of the light-emitting module according to the second embodiment to show a positional relationship of a light-emitting device, a wiring substrate, a first conductor, and a second conductor in the light-emitting module according to the second embodiment.

FIG. 12 schematically illustrates a bottom view of a light-emitting module according to Modified Example 1 of the second embodiment to show a positional relationship of a light-emitting device, a wiring substrate, a first conductor, and a second conductor in the light-emitting module according to Modified Example 1 of the second embodiment.

FIG. 13 schematically illustrates a bottom view of a light-emitting module according to Modified Example 3 of the second embodiment to show a positional relationship of a light-emitting device, a wiring substrate, a first conductor, and a second conductor in the light-emitting module according to Modified Example 2 of the second embodiment.

FIG. 14 schematically illustrates a cross-sectional view of a light-emitting module according to Modified Example 3 of the second embodiment.

FIG. 15 schematically illustrates a cross-sectional view of a light-emitting module according to Modified Example 4 of the second embodiment.

FIG. 16 schematically illustrates a cross-sectional view of a light-emitting module according to Modified Example 5 of the second embodiment.

FIG. 17 schematically illustrates a bottom view of the light-emitting module according to Modified Example 5 of the second embodiment to show a positional relationship of a light-emitting device, a wiring substrate, a first conductor, and a second conductor in the light-emitting module according to Modified Example 5 of the second embodiment.

FIG. 18 schematically illustrates a bottom view of a light-emitting module according to Modified Example 6 of the second embodiment to show a positional relationship of a light-emitting device, a wiring substrate, a first conductor, and a second conductor in the light-emitting module according to Modified Example 6 of the second embodiment.

FIG. 19 schematically illustrates a bottom view of a light-emitting module according to Modified Example 7 of the second embodiment to show a positional relationship of a light-emitting device, a wiring substrate, a first conductor, and a second conductor in the light-emitting module according to Modified Example 7 of the second embodiment.

### DETAILED DESCRIPTION OF EMBODIMENTS

Some embodiments will be described below with reference to the accompanying drawings. Because the drawings schematically illustrate those embodiments, each drawing may exaggerate scales, distances, intervals, a positional relationship, and other arrangements of members and may omit illustrations of some of the members. Herein, a side toward which the arrow of the X-axis points is defined as the +X side, and a side opposite to the +X side is defined as the −X side.

Likewise, a side toward which the arrow of the Y-axis points is defined as the +Y side, and a side opposite to the +Y side is defined as the −Y side. A side toward which the arrow of the Z-axis points will be referred to as “above” an object, and a side opposite to “above” will be referred to as “below” the object. A view of an object from above the object is defined as top view, which is synonymous with plan view. Some cross-sectional views are cross-sectional end views, which illustrate only cut surfaces.

In the description below, components having substantially the same function will be shown with the same reference numerals, and repeated descriptions of such components may be omitted. Terms representing particular directions or locations (e.g., “up/upper, ” “down/lower, ” and other terms containing the meanings of these terms) may be used. These terms are used merely for the sake of ease of explanation, representing relative directions or relative positions in the referenced drawings. As far as the relative directions or positions mentioned by the terms “upper,” “lower,” and the like designate the same directions or positions in the reference drawings, drawings other than shown in the present disclosure, actual products, and the like do not have to be the same arrangement as shown in the reference drawings. The term “parallel” as used in the present specification encompasses not only the case in which neither two straight lines, sides, surfaces, etc., nor their extensions intersect but also the case in which two straight lines, sides, surfaces, etc., intersect to form an angle of 10° or less. The positional relationship represented as “on” in the present specification includes both the case in which components are in contact with each other and the case in which a component is not in contact with but is located above another component.

### First Embodiment

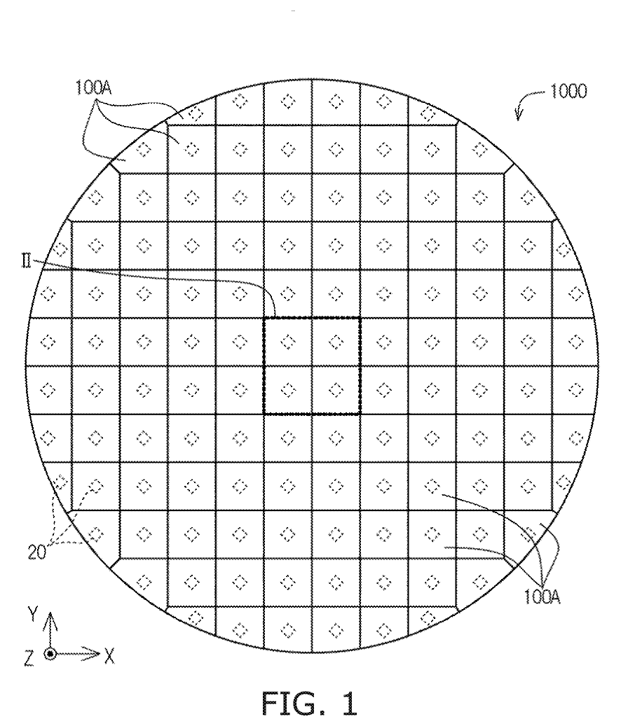

A light-emitting device 1000 according to a first embodiment will be described below with reference to FIGS. 1 to 9. FIG. 1 schematically illustrates a top view of the light-emitting device 1000, as viewed from a light-emitting surface side of the light-emitting device. As illustrated in FIG. 1, the X direction and Y direction are defined as two mutually perpendicular directions parallel to the light-emitting surface of the light-emitting device 1000. The direction orthogonal to both the X direction and the Y direction is defined as the Z direction. Herein, the Z direction may be referred to as the vertical direction.

The light-emitting device 1000 includes a support body 10, light sources 20, conductive members 30, and an insulating member 40. The support body 10 has a first surface 101 and a second surface 102 opposite to the first surface 101. The support body 10 includes first through holes 11H and second through holes 12H. Each light source 20 is positioned at the first surface 101 side of the support body 10. Each light source 20 includes a first electrode 21 and a second electrode 22. The conductive members 30 for each light source 20 include a first conductive member 31 and a second conductive member 32. The first conductive member 31 includes a first part 31A and a second part 31B. The first part 31A is positioned within the respective first through hole 11H. The second part 31B is continuous with the first part 31A. The second part 31B is positioned at the second surface 102 side of the support body 10. The first conductive member 31 is electrically connected to the first electrode 21. The second conductive member 32 includes a third part 32A and a fourth part 32B. The third part 32A is positioned within the second through hole 12H. The fourth part 32B is continuous with the third part 32A. The fourth part 32B is positioned at the second surface 102 side of the support body 10. The second conductive member 32 is electrically connected to the second electrode 22. As viewed from a second surface 102 side, the insulating member 40 overlaps at least a portion of the first part 31A. Likewise, as viewed from the second surface 102 side, the insulating member 40 covers at least a portion of the third part 32A. As viewed from the second surface 102 side, a distance L1, which is the shortest distance from an exposed region of the first conductive member 31 that is exposed to the second surface 102 side and uncovered by the insulating member 40 to an exposed region of the second conductive member 32 that is exposed to the second surface 102 side and uncovered by the insulating member 40, is greater than a distance L2, which is the shortest distance from the first through hole 11H to the second through hole 12H. The expression “as viewed from a second surface side” as used in the present specification is synonymous with as viewing an object from below, namely, in bottom view.

In the present embodiment, as viewed from the second surface 102 side, the distance L1, which is the shortest distance from the exposed region of the first conductive member 31 to the exposed region of the second conductive member 32, is greater than the distance L2, which is the shortest distance from the first through hole 11H to the second through hole 12H. With this configuration, when mounting the light-emitting device 1000 on the wiring substrate, a first conductor, which electrically connects the first conductive member 31 to the wiring substrate, and a second conductor, which electrically connects the second conductive member 32 to the wiring substrate, are less likely to come into contact with each other. This can reduce the occurrence of short-circuiting in the light-emitting device 1000. Consequently, this facilitates improvement in the reliability of the light-emitting device 1000.

Components constituting the light-emitting device 1000 will be described below in detail. As illustrated in FIG. 1, the light-emitting device 1000 has a circular shape in the top view. However, the light-emitting device 1000 may have any other shape in the top view; the light-emitting device 1000 may have a triangular shape, a quadrilateral shape, a hexagonal shape, another polygonal shape, or an elliptical shape.

### Support body 10

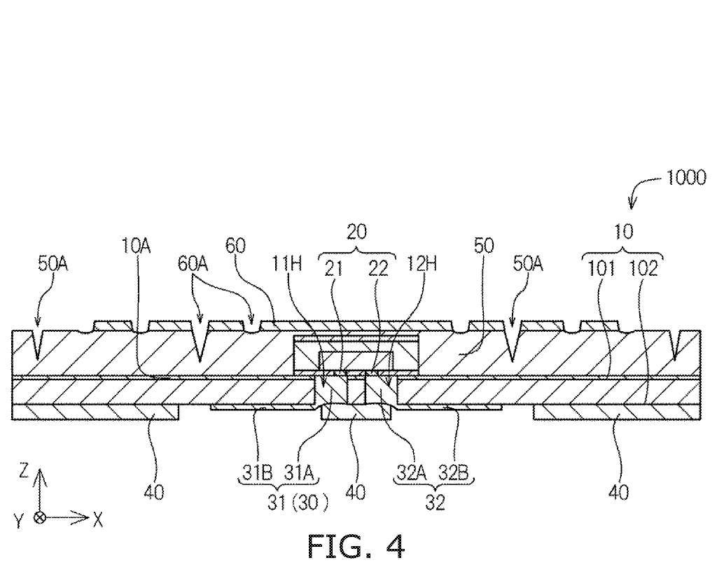

As illustrated in FIG. 4, the support body 10 is a member positioned below a light source 20.

In the present embodiment, the light source 20 is positioned above the support body 10 with a bonding layer 10A therebetween. The support body 10 has a first surface 101 and a second surface 102 opposite to the second surface 102. The support body 10 includes a first through hole 11H and a second through hole 12H. The first through hole 11H has openings in the first surface 101 and the second surface 102. The second through hole 12H has openings in the first surface 101 and the second surface 102. An example of a material for the bonding layer 10A is a sheet-shaped optical clear adhesive (OCA).

The material of the support body 10 is not particularly limited. For example, the material for the support body 10 may be an insulating material such as resin. Examples of such a resin member for the support body 10 include: thermoplastic resins such as acrylic resin, polycarbonate resin, cyclic polyolefin resin, polyethylene terephthalate resin, and polyester resin; and thermosetting resins such as epoxy resin and silicone resin.

The support body 10 is preferably reflective for light emitted by the light source 20. With the light-reflective support body 10, the light extraction efficiency of the light-emitting device 1000 can be easily improved. The support body 10 may be made of a resin member and a reflector contained in the resin member. Examples of the material for the reflector in the support body 10 include optical reflective particles of titania, silica, alumina, zinc oxide, magnesium oxide, zirconia, yttria, calcium fluoride, magnesium fluoride, niobium pentoxide, barium titanate, tantalum pentoxide, barium sulfate, glass, and other materials. Alternatively, the reflector in the support body 10 may be a gas such as nitrogen or oxygen. Moreover, the support body 10 may contain both the light-scattering particles and the gas as the reflectors.

The support body 10 is preferably a resin member containing a gas such as nitrogen or oxygen. A refractive index of a gas such as nitrogen or oxygen is generally lower than a refractive index of a base material such as a resin member. Accordingly, when a portion of light from the light source 20 enters the resin member, a portion of the light is likely to be totally reflected at an interface between the resin member and the gas. As a result, the light traveling downward from the light source 20 is easily totally-reflected by the support body. This configuration facilitates improvement in the light extraction efficiency of the light-emitting device 1000.

The bonding layer 10A may be configured to reflect light emitted by the light source 20. With the light-reflective bonding layer 10A, the light extraction efficiency of the light-emitting device 1000 can be easily improved. The bonding layer 10A can include a resin member and a reflector contained in the resin component. A material for the resin member in the bonding layer 10A may be the same as the material of the resin member in the support body 10. Likewise, a material for the reflector in the bonding layer 10A may be the same as the material of the reflector in the support body 10.

In a cross-sectional view, a ratio of an area of the reflector in the bonding layer 10A to an area of the resin member in the bonding layer 10A is preferably lower than a ratio of an area of the reflector in the support body 10 to an area of the resin member in the support body 10. Accordingly, light that has been totally reflected by the support body 10 and traveling upward is less likely to be blocked by the reflector in the bonding layer 10A. This facilitates improvement in the light extraction efficiency of the light-emitting device 1000. The bonding layer 10A does not necessarily contain the reflector.

A refractive index of the resin member in the bonding layer 10A is preferably lower than a refractive index of a resin member in a light-transmissive member 50, which will be described below. With this configuration, a portion of the light emitted from the light source 20 and traveling from the light-transmissive member 50 toward the bonding layer 10A is more likely to be totally-reflected at the interface between the light-transmissive member 50 and the bonding layer 10A. Accordingly, light leaking downward from the light-emitting device 1000 can be reduced, thereby facilitating improvement in the light extraction efficiency. The term “refractive index” used in the present specification refers to a refractive index at an emission peak wavelength of the light source 20.

### Light Source 20

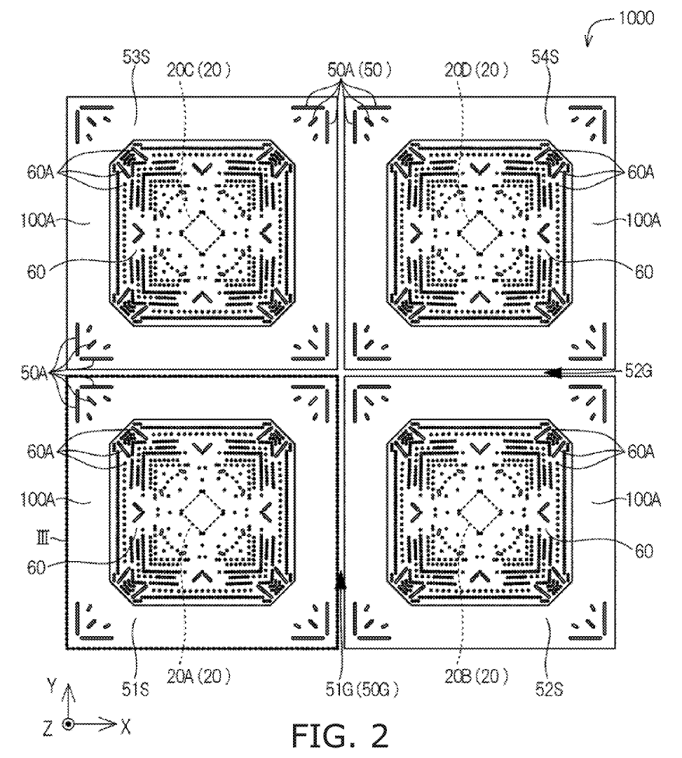

As illustrated in FIG. 2, the light-emitting device 1000 includes the plurality of light sources 20, which include a first light source 20A, a second light source 20B, a third light source 20C, and a fourth light source 20D. Alternatively, the light-emitting device 1000 may include a single light source 20.

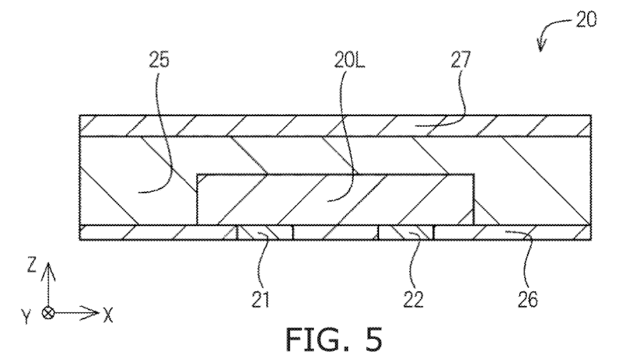

As illustrated in FIG. 5, a light source 20 includes a light-emitting element 20L. The light-emitting element 20L includes a semiconductor layered body. This semiconductor layered body includes, for example, a substrate made of sapphire, gallium nitride substrate, or another material; an n-type semiconductor layer and a p-type semiconductor layer disposed on the substrate; and a light-emitting layer disposed between the n-type semiconductor layer and the p-type semiconductor layer. Furthermore, the light-emitting element 20L includes: an n-side electrode electrically connected to the n-type semiconductor layer; and a p-side electrode electrically connected to the p-type semiconductor layer. The n-side electrode and the p-side electrode form portions of a lower surface of the light-emitting element 20L. Moreover, the light source 20 includes: an n-side metal post electrically connected to the n-side electrode; and a p-side post electrically connected to the p-side electrode. In the present embodiment, a first electrode 21 includes both the n-side electrode and the n-side metal post. However, the light source 20 does not necessarily include the n-side metal post. When the light source 20 does not include the n-side metal post, the first electrode 21 may be formed by the n-side electrode. In the present embodiment, a second electrode 22 includes both the p-side electrode and the p-side metal post. However, the light source 20 does not necessarily include the p-side metal post. When the light source 20 does not include the p-side metal post, the second electrode 22 may be formed by the p-side electrode. Each of the p-side metal post and n-side metal post contains copper (Cu) and/or nickel (Ni), for example. However, the light source 20 does not necessarily include the substrate made of sapphire, gallium nitride, or another material. This configuration facilitates reduction in size of the light source 20 in the vertical direction. In the present embodiment, the first electrode 21 and the second electrode 22 are arranged in a first direction (X direction).

The light-emitting layer may have a structure with a single active layer, such as a double heterostructure and a single quantum well (SQW) structure, or a structure with a group of active layers, such as a multiple quantum well (MQW) structure. The light-emitting layer is configured to emit visible light or ultraviolet light (ray). The light-emitting layer is configured to emit blue to red light as the visible light. The semiconductor layered body including such a light-emitting layer can contain, for example, InₓAl_{y}Ga_{1-x-y}N (0 ≤ x, 0 ≤ y, and x + y ≤ 1). The semiconductor layered body can include at least one light-emitting layer configured to emit the above-described light. For example, the semiconductor layered body may include one or more light-emitting layers between the n-type semiconductor layer and the p-type semiconductor layer or may have multiple repetitions of a structure in which the n-type semiconductor layer, the light-emitting layer, and the p-type semiconductor layer are stacked in this order. When the semiconductor layered body includes a plurality of light-emitting layers, the light-emitting layers may have different emission peak wavelengths or the same emission peak wavelength. The expression “same emission peak wavelength” may encompass, for example, variations of several nanometers. Such a combination of light-emitting layers can be appropriately selected, and in the case in which the semiconductor layered body includes two light-emitting layers, for example, the combination of light-emitting layers can be selected from blue light and blue light, green light and green light, red light and red light, ultraviolet light and ultraviolet light, blue light and green light, blue light and red light, and green light and red light. The light-emitting layers may include a plurality of active layers having different emission peak wavelengths or the same emission peak wavelength.

In the present embodiment, each light source 20 includes a single light-emitting element 20L. Alternatively, however, each of the light sources 20 (first light source 20A, second light source 20B, third light source 20C, or fourth light source 20D) may include a plurality of light-emitting elements 20L. When each light source 20 includes a plurality of light-emitting elements, the emission peak wavelengths of the light-emitting elements may be the same as or different from one another. As an example, when each light source 20 includes two light-emitting elements, the emission peak wavelengths of light-emitting elements can be selected by using any of the following light pairs: blue light and green light; blue light and red light; ultraviolet light and blue light; ultraviolet light and green light; ultraviolet light and red light; and green light and red light. As another example, when each light source 20 includes three light-emitting elements, the emission peak wavelengths of light-emitting elements can be selected by using any of the following light combinations: blue light, green light, and red light; ultraviolet light, green light, and red light; ultraviolet light, blue light, and green light; ultraviolet light, blue light, and red light; ultraviolet light, green light, and red light; and blue light, blue light, and green light.

As illustrated in FIG. 5, the light source 20 may further include a light-transmissive member (referred to below as a first light source light-transmissive member 25). The first light source light-transmissive member 25 covers an upper surface and side surfaces of the light-emitting element 20L. The first light source light-transmissive member 25 can protect the light-emitting element 20L. The first light source light-transmissive member 25 may be disposed to expose at least a portion of the upper surface of the light-emitting element 20L. This configuration facilitates size reduction of the light source 20 in the vertical direction.

For example, the first light source light-transmissive member 25 is configured to transmit light emitted by the light-emitting element 20L. The first light source light-transmissive member 25 contains a light-transmissive resin and may further contain a phosphor. Examples of such a light-transmissive resin include a silicone resin and an epoxy resin. Examples of the phosphor include yttrium-aluminum-garnet based phosphors (such as (Y,Gd)₃(Al,Ga)₅O₁₂:Ce), lutetium-aluminum-garnet based phosphors (such as Lu₃(Al,Ga)₅O₁₂:Ce), terbium-aluminum-garnet based phosphors (such as Tb₃(Al,Ga)₅O₁₂:Ce), CCA based phosphors (such as Ca₁₀(PO₄)₆Cl₂:Eu), SAE based phosphors (such as Sr₄Al₁₄O₂₅:Eu), chlorosilicate based phosphors (such as Ca₈MgSi₄O₁₆Cl₂:Eu), silicate based phosphors (such as (Ba,Sr,Ca,Mg)₂SiO₄:Eu), oxynitride based phosphors such as β-SiAlON based phosphors (such as (Si,Al)₃(O,N)₄:Eu) and α-SiAlON based phosphors (such as Ca(Si,Al)₁₂(O,N)₁₆:Eu), nitride based phosphors such as LSN based phosphors (such as (La,Y)₃Si₆N₁₁:Ce), BSESN based phosphors (such as (Ba,Sr)₂Si₅N₈:Eu), SLA based phosphors (such as SrLiAl₃N₄:Eu), CASN based phosphors (such as CaAlSiN₃:Eu), and SCASN based phosphors (such as (Sr,Ca)AlSiN₃:Eu), fluoride based phosphors such as KSF based phosphors (such as K₂SiF₆:Mn), KSAF based phosphors (such as K₂(Si₁₋ₓAlₓ)F₆₋ₓ:Mn, where x satisfies 0 < x < 1), and MGF based phosphors (such as 3.5MgO∙0.5MgF₂∙GeO₂:Mn), quantum dots having the perovskite structure (such as (Cs,FA,MA)(Pb,Sn)(F,Cl,Br,I)₃, where FA and MA respectively represent formamidinium and methylammonium), group II–VI quantum dots (such as CdSe), group III–V quantum dots (such as InP), and quantum dots having the chalcopyrite structure (such as (Ag,Cu)(In,Ga)(S,Se)₂). As the phosphor to be added to the first light source light-transmissive member 25, a single type of phosphor or multiple types of phosphors may be used.

A wavelength conversion sheet containing the phosphor described above may be disposed on or above the light-emitting device 1000. The wavelength conversion sheet absorbs a portion of blue light from the light source 20 and emits yellow light, green light, and/or red light, and thus can serve as a planar light source that emits white light. For example, white light can be obtained by combining the light source 20 that emits blue light with a wavelength conversion sheet containing a phosphor that emits yellow light. Alternatively, the light source 20 that emits blue light may be combined with the wavelength conversion sheet containing a red phosphor and a green phosphor. The light source 20 that emits blue light may be combined with a plurality of wavelength conversion sheets. As the plurality of wavelength conversion sheets, a wavelength conversion sheet containing a phosphor that emits red light and a wavelength conversion sheet containing a phosphor that emits green light can be selected. The light source 20 that includes the light-emitting element 20L that emits blue light and the first light source light-transmissive member 25 that contains phosphor that emits red light may be combined with the wavelength conversion sheet that contains phosphor that emits green light.

As the phosphor that emits yellow light to be used for the wavelength conversion sheet, it is preferable to use yttrium-aluminum-garnet based phosphors described above. As the phosphors that emit green light to be used for the wavelength conversion sheet, it is preferable to use a phosphor that emits light with a narrow half-width at the peak wavelength, such as quantum dots having the perovskite structure, group III-V quantum dots or quantum dots having the chalcopyrite structure described above. As the phosphor that emits red light to be used for the wavelength conversion sheet, it is preferable to use a phosphor that emits light with a narrow half-width at the emission peak wavelength, similar to the phosphor that emits green light, such as a KSF-based phosphors, a KSAF-based phosphor, group III-V quantum dots, or quantum dots having the chalcopyrite structure described above.

Moreover, a bandpass filter that transmits light within a specific wavelength range and reflects light outside that range may be disposed between the wavelength conversion sheet and the light source 20. For example, the bandpass filter may be a dichroic sheet. This bandpass filter preferably transmits only blue light and reflects light of other colors (such as green light and red light). With this structure, only blue light among light emitted from the light source 20 enters the wavelength conversion sheet. Accordingly, by using this bandpass filter together with a wavelength conversion sheet that absorbs a portion of blue light from the light source 20 to emit white light, the white light can be emitted easily from the wavelength conversion sheet. Also, with this structure, light transmitted through the bandpass filter and then reflected by the wavelength conversion sheet, which is thus light of a color other than blue (such as green light, red light), can be inhibited from being returned toward the light source 20. Consequently, luminance unevenness in the light-emitting device 1000 can be reduced.

Moreover, a diffusion sheet may be disposed between the bandpass filter and the light source 20. The diffusion sheet transmits the light from the light source 20 and diffuses the transmitted light when the light is emitted from the diffusion sheet toward the bandpass filter. Consequently, luminance unevenness in the light-emitting device 1000 can be reduced. For the diffusion sheet, a material with a low light absorption property for light emitted by the light-emitting element 20L is preferably used. Examples of such a diffusion sheet include polycarbonate, polystyrene, acrylic, and polyethylene. The diffusion sheet may include a light-emitting surface having small irregularities or an optical diffusing film that exhibits a light diffusing property. The diffusion sheet may be formed of a single layer or a stack of a plurality of layers.

Moreover, a prism sheet may be disposed on or above the wavelength conversion sheet. A surface of the prism sheet is provided with a plurality of prisms that extend in one direction. As the prism sheet, a single prism sheet or a stack of a plurality of prism sheets may be used. When using a stack of a plurality of prism sheets, for example, one of the prism sheets can extend in the X direction, and another of the prism sheets can extend in the Y direction. Using the prism sheet allows light emitted from the prism sheet to travel in a direction perpendicular to a light-emitting surface of the prism sheet, thereby increasing the luminance of the light-emitting device 1000 in a top view.

The light source 20 further includes a covering member 26. The covering member 26 is reflective for light emitted by the light-emitting element 20L. The covering member 26 is disposed at a lower surface side of the light-emitting element 20L. The covering member 26 is disposed with lower surfaces of the first electrode 21 and the second electrode 22 exposed without being covered by the covering member 26. The covering member 26 is also disposed on a lower surface of the first light source light-transmissive member 25 covering the side surface of the light-emitting element 20L.

As illustrated in FIG. 5, the light source 20 can further include a light adjustment member (hereinafter referred to as the light-source light adjustment member 27). The light-source light adjustment member 27 forms at least a portion of the upper surface of the light source 20. The light-source light adjustment member 27 is positioned above the light-emitting element 20L. In a top view, the light-source light adjustment member 27 overlaps the light-emitting element 20L. In the overlapping area, the light-source light adjustment member 27 is positioned above the light-emitting element 20L. The light-source light adjustment member 27 is positioned above the first light source light-transmissive member 25 and is configured to adjust the amount and/or direction of light emitted from the upper surface of the first light source light-transmissive member 25. The light-source light adjustment member 27 has both light reflectivity and transmissivity for light emitted by the light-emitting element 20L. A portion of the light emitted from the upper surface of the first light source light-transmissive member 25 is reflected by the light-source light adjustment member 27, and another portion of the light is transmitted through the light-source light adjustment member 27. Light transmittance of the light-source light adjustment member 27 at the emission peak wavelength of the light-emitting element 20L is preferably in the range of 1 to 50%, and more preferably in the range of 3 to 30%. With the light source 20 including the light-source light adjustment member 27, the region directly above the light source 20 can be inhibited from being excessively bright. This configuration facilitates reduction of luminance unevenness in the light-emitting device 1000.

The light-source light adjustment member 27 can be formed of, for example, a resin member and a reflector included in the resin member. The resin member in the light-source light adjustment member 27 may be made of the same material as the resin member in the support body 10. The reflector in the light-source light adjustment member 27 may be made of the same material as the reflector in the support body 10. More specifically, the light-source light adjustment member 27 may be made of a metal member, such as aluminum or silver, or a dielectric multilayer film.

The light source 20 does not necessarily include the light-source light adjustment member 27. In this case, an upper surface of the light source 20 may be formed of an upper surface of the light-emitting element 20L and/or an upper surface of the first light source light-transmissive member 25. This configuration facilitates size reduction of the light source 20 in the vertical direction, as compared with a configuration in which the light source 20 includes the light-source light adjustment member 27 positioned above the light-emitting element 20L. In another example, the light source 20 does not necessarily include the covering member 26. In this case, a lower surface of the light source 20 may be formed of a lower surface of the light-emitting element 20L and/or a lower surface of the first light source light-transmissive member 25. In still another example, the light source 20 may include the light-emitting element 20L alone. In yet another example, the light source 20 does not necessarily include the first light source light-transmissive member 25 or the covering member 26, in which case the light-source light adjustment member 27 may be positioned on the upper surface of the light-emitting element 20L. In further another example, the light source 20 does not necessarily include the first light source light-transmissive member 25, in which case, the light-source light adjustment member 27 may be positioned on or above the upper surface of the light-emitting element 20L, and the covering member 26 may be positioned on or below the lower surface of the light-emitting element 20L. Alternatively, the light source 20 may further include a mounting substrate and a light-emitting element mounted on the mounting substrate. Furthermore, when the mounting substrate includes a recess, the light-emitting element 20 may be positioned within the recess.

The light source 20 may have any appropriate shape in a top view. For example, the light source 20 may have a circular shape or a polygonal shape such as a triangular shape, a quadrilateral shape, a hexagonal shape, or an octagonal shape in the top view. When the light source 20 has a quadrilateral shape in the top view, a pair of side edges of the light source 20 may be parallel to the X direction or inclined with respect to the X direction. In the present embodiment, a pair of the outer edges of the light source 20 are inclined at 45° with respect to the X-direction.

### Conductive Member 30

The conductive members 30 are members employed to supply power to the light sources 20. Any appropriate material may be used for the conductive members 30. The conductive members 30 may be made of an electroconductive paste containing a resin and metal particles dispersed in the resin. Examples of such a resin in the conductive members 30 include an epoxy resin and a phenolic resin. Furthermore, the conductive members 30 may contain metal particles such as copper or silver particles.

The conductive members 30 may contain a thermosetting resin, and the support body 10 may contain a thermoplastic resin. In this case, it is preferable that a melting point of the thermoplastic resin in the support body 10 be higher than a curing temperature of the thermosetting resin in the conductive members 30. With this structure, the thermoplastic resin in the support body 10 does not melt even when the thermosetting resin in the conductive members 30 reaches the curing temperature of the thermosetting resin, so that the light reflectivity of the support body 10 is less likely to be decreased. The thermosetting resin in the conductive members 30 can be an epoxy resin, and the thermoplastic resin in the support body 10 can be polyethylene terephthalate. The curing temperature of the epoxy resin is in the range of approximately 100 to 150° C. The melting point of polyethylene terephthalate is approximately 250° C.

The conductive members 30 for each light source 20 include the first conductive member 31 and the second conductive member 32. The first conductive member 31 includes the first part 31A and the second part 31B. The first part 31A is positioned within the first through hole 11H. The second part 31B is continuous with the first part 31A. The second part 31B is positioned at the second surface 102 side of the support body 10. The first conductive member 31 is electrically connected to the first electrode 21 of the light source 20. In the present embodiment, the first conductive member 31 is in contact with the first electrode 21. The second conductive member 32 includes the third part 32A and the fourth part 32. The third part 32A is positioned within the second through hole 12H. The fourth part 32B is continuous with the third part 32A. The fourth part 32B is positioned at the second surface 102 side of the support body 10. The second conductive member 32 is electrically connected to the second electrode 22 of the light source 20. In the present embodiment, the second conductive member 32 is in contact with the respective second electrodes 22. In the present embodiment, each pair of first conductive member 31 and second conductive member 32 are arranged in the first direction (X direction).

### Insulating Member 40

The insulating member 40 is formed so as to partially cover the conductive member 30, that is, portions of the conductive member 30. Any appropriate material may be used for the insulating member 40. Examples of the material for the insulating member 40 include a sheet-shaped optical transparent adhesive and a resist. The insulating member 40 may be formed of a single layer or a plurality of layers stacked in the vertical direction. For example, the insulating member 40 may be formed of a single layer of optically transparent adhesive or a stacked body of an optically transparent adhesive and a resist. The insulating member 40 preferably has an adhesive property. With this configuration, when the light-emitting device 1000 is mounted on a wiring substrate, the insulating member 40 comes into contact with the wiring substrate, thereby facilitating improvement in the bonding strength between the light-emitting device 1000 and the wiring substrate.

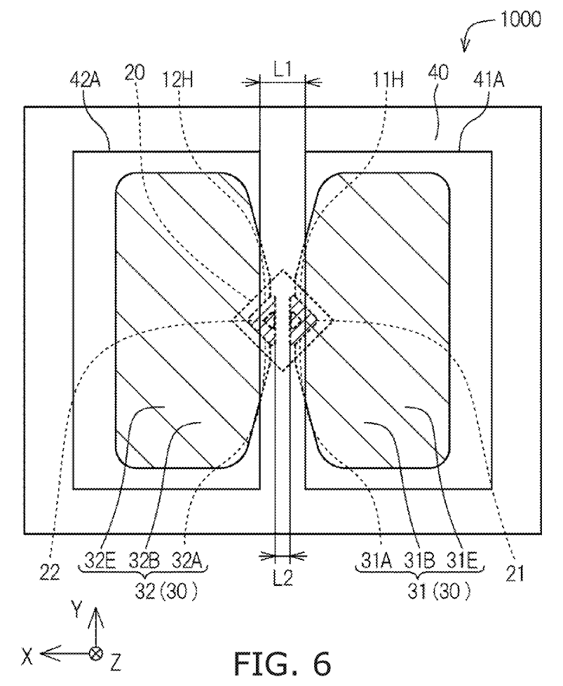

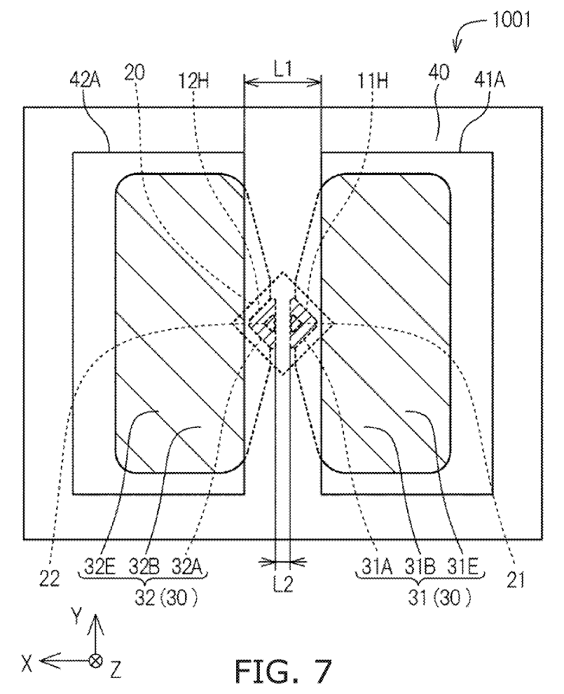

As illustrated in FIG. 6, the insulating member 40 overlaps at least a portion of the first part 31A of the first conductive member 31, as viewed from the second surface side. Likewise, the insulating member 40 overlaps at least a portion of the third part 32A of a second conductive member 32, as viewed from the second surface side. In FIGS. 6 and 7, the areas of the first part 31A and the third part 32A are hatched with diagonal lines running from the lower left to the upper right. In FIG. 6, an outer edge of the first through hole 11H is aligned with an outer edge of the first part 31A, and an outer edge of the second through hole 12H is aligned with an outer edge of the third part 32A.

As illustrated in FIG. 6, a region of the first conductive member 31 is exposed without being covered by the insulating member 40, as viewed from the second surface side. Herein, the region of the first conductive member 31 exposed without being covered by the insulating member 40 as viewed from the second surface side may be referred to as a first exposed conductive region 31E. In FIGS. 6 and 7, an area of the first exposed conductive region 31E is hatched diagonal lines running from lower right to upper left. In the present embodiment, the first exposed conductive region 31E includes a portion of the first part 31A and a portion of the second part 31B. The portion of the first part 31A is preferably exposed without being covered by the insulating member 40, as viewed from the second surface side. This configuration facilitates an increase in an area of the first exposed conductive region 31E. Accordingly, when the first exposed conductive region 31E is located on a wiring substrate with a conductor therebetween, a contact area between the first exposed conductive region 31E and the conductor can be easily increased. This facilitates the reduction of lighting failures due to poor contact between the first exposed conductive region 31E and the conductor. As a result, the reliability of the light-emitting device 1000 can be improved.

As illustrated in FIG. 6, a region of the second conductive member 32 is exposed without being covered by the insulating member 40, as viewed from the second surface side. Herein, the region of the second conductive member 32 exposed without being covered by the insulating member 40 as viewed from the second surface side may be referred to as a second exposed conductive region 32E. In FIGS. 6 and 7, an area of the second exposed conductive region 32E is hatched diagonal lines running from lower right to upper left. In the present embodiment, the second exposed conductive region 32E includes a portion of the third part 32A and a portion of the fourth part 32B. The portion of the third part 32A is preferably exposed without being covered by the insulating member 40, as viewed from the second surface side. This configuration facilitates an increase in an area of the second exposed conductive region 32E. Accordingly, when the second exposed conductive region 32E is located on a wiring substrate with a conductor therebetween, a contact area between the second exposed conductive region 32E and the conductor can be easily increased. This facilitates the reduction of lighting failures due to poor contact between the second exposed conductive region 32E and the conductor. As a result, the reliability of the light-emitting device 1000 can be improved.

As illustrated in FIG. 6, the distance L1, which is the shortest distance from the first exposed conductive region 31E to the second exposed conductive region 32E, is preferably greater than the distance L2, which is the shortest distance from the first through hole 11H to the second through hole 12H. With this configuration, the first conductor that electrically connects the first exposed conductive region 31E to the wiring substrate and the second conductor that electrically connects the second exposed conductive region 32E to the wiring substrate are less likely to come into contact with each other when the light-emitting device 1000 is mounted on the wiring substrate. This can reduce short-circuiting of the light-emitting device 1000. As a result, the reliability of the light-emitting device 1000 can be improved.

A maximum length of the first exposed conductive region 31E in the first direction (X-direction) is preferably greater than a maximum length of the light source 20 in the first direction. In other words, a maximum length of the region of the first conductive member 31 exposed without being covered by the insulating member 40 in the first direction is preferably greater than the maximum length of the light source 20 in the first direction, as viewed from the second surface side. This configuration facilitates an increase in an area of the first exposed conductive region 31E. When the light-emitting device 1000 is mounted on a wiring substrate, a contact area between a first conductor that electrically connects a first exposed conductive region 31E to the wiring substrate and the first exposed conductive region 31E can be easily increased. This facilitates the reduction of lighting failures due to poor contact between the first conductor and the first exposed conductive region 31E, thereby improving the reliability of the light-emitting device 1000. Likewise, a maximum length of the first exposed conductive region 31E in a second direction (Y direction) perpendicular to the first direction is preferably greater than a maximum length of the light source 20 in the second direction.

A maximum length of the second exposed conductive region 32E in the first direction is preferably greater than the maximum length of the light source 20 in the first direction. In other words, a maximum length of the region of the second conductive member 32 exposed without being covered by the insulating member 40 in the first direction is preferably greater than the maximum length of the light source 20 in the first direction, as viewed from the second surface side. This configuration facilitates an increase in an area of the second exposed conductive region 32E. When the light-emitting device 1000 is mounted on a wiring substrate, a contact area between a second conductor that electrically connects the second exposed conductive region 32E to the wiring substrate and the second exposed conductive region 32E can be easily increased. This facilitates the reduction of lighting failures due to poor contact between the second conductor and the second exposed conductive region 32E, thereby improving the reliability of the light-emitting device 1000. Likewise, a maximum length of the second exposed conductive region 32E in the second direction is preferably greater than the maximum length of the light source 20 in the second direction.

In the present embodiment, as illustrated in FIG. 6, the insulating member 40 includes a first aperture 41A and a second aperture 42A. The first aperture 41A is a through hole having openings in the upper surface of the insulating member 40 and the lower surface thereof. Likewise, the second aperture 42A is a through hole having openings in the upper surface of the insulating member 40 and the lower surface thereof. The first exposed conductive region 31E is positioned within the first aperture 41A, as viewed from the second surface side. Likewise, the second exposed conductive region 32E is positioned within the second aperture 42A, as viewed from the second surface side.

A maximum length of the first aperture 41A in the first direction (X direction) is preferably greater than the maximum length of the light source 20 in the first direction. This configuration facilitates an increase in the area of the first exposed conductive region 31E positioned within the first aperture 41A, as viewed from the second surface side. Accordingly, when the light-emitting device 1000 is mounted on a wiring substrate, a contact area between a first conductor that electrically connects a first exposed conductive region 31E to the wiring substrate and the first exposed conductive region 31E can be easily increased. This facilitates the reduction of lighting failures due to poor contact between the first conductor and the first exposed conductive region 31E, thereby improving the reliability of the light-emitting device 1000. Likewise, a maximum length of the first aperture 41A in the second direction (Y direction) is preferably greater than the maximum length of the light source 20 in the second direction.

A maximum length of the second aperture 42A in the first direction (X direction) is preferably greater than the maximum length of the light source 20 in the first direction. This configuration facilitates an increase in the area of the second exposed conductive region 32E positioned within the second aperture 42A, as viewed from the second surface side. Accordingly, when the light-emitting device 1000 is mounted on a wiring substrate, a contact area between a second conductor that electrically connects the second exposed conductive region 32E to the wiring substrate and the second exposed conductive region 32E can be easily increased. This facilitates the reduction of lighting failures due to poor contact between the second conductor and the second exposed conductive region 32E, thereby improving the reliability of the light-emitting device 1000. Likewise, a maximum length of the second aperture 42A in the second direction (Y direction) is preferably greater than the maximum length of the light source 20 in the second direction.

As in a light-emitting device 1001 illustrated in FIG. 7, an entirety of the first part 31A may be completely overlapped by an insulating member 40, as viewed from the second surface side. This configuration facilitates an increase in the shortest distance L1 from a first exposed conductive region 31E to a second exposed conductive region 32E. With this configuration, the first conductor that electrically connects the first exposed conductive region 31E to the wiring substrate and the second conductor that electrically connects the second exposed conductive region 32E to the wiring substrate are less likely to come into contact with each other when the light-emitting device 1001 is mounted on the wiring substrate. This can reduce short-circuiting of the light-emitting device 1001. As a result, the reliability of the light-emitting device 1001 can be improved. Likewise, an entirety of a third part 32A may be overlapped with the insulating member 40, as viewed from the second surface side.

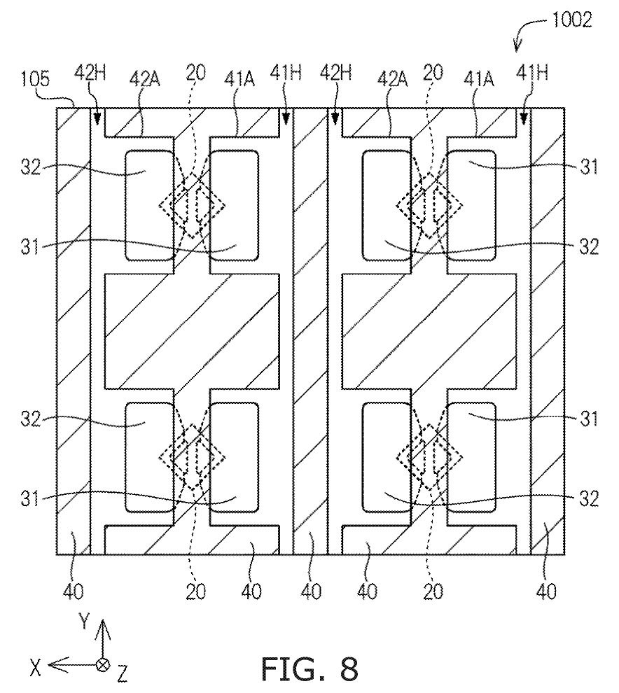

As in a light-emitting device 1002 illustrated in FIG. 8, an insulating member 40 may include first holes 41H and second holes 42H. The first holes 41H communicate between an outer edge 105 of the light-emitting device 1002 and first apertures 41A, as viewed from the second surface side. With the insulating member 40 having the first holes 41H, gas such as nitrogen or oxygen present inside the first apertures 41A can smoothly escape to an exterior of the light-emitting device 1002 through the first holes 41H when the light-emitting device 1002 is mounted on a wiring substrate. This configuration facilitates reduction of void formation in a conductor that electrically connects the light-emitting device 1002 to the wiring substrate. As a result, the reliability of the light-emitting device 1002 can be improved. The second holes 42H communicate between the outer edge 105 of the light-emitting device 1002 and second apertures 42A, as viewed from the second surface side. With the insulating member 40 having the second holes 42H, gas such as nitrogen or oxygen present inside the second aperture 42A can smoothly escape to the exterior of the light-emitting device 1002 through the second holes 42H when the light-emitting device 1002 is mounted on a wiring substrate. The first holes 41H and the second holes 42H preferably extend from the upper surface of the insulating member 40 to the lower surface thereof. Accordingly, the size of the first hole 41H and the size of the second hole 42H can be increased, which allows the gas to escape more smoothly to the exterior. Alternatively, each of the first holes 41H and/or the second holes 42H may be a recess that has an opening only in the upper surface of the insulating member 40 or only in the lower surface of the insulating member 40. In FIG. 8, an area of the insulating member 40 is hatched with diagonal lines running from the lower left to the upper right.

### Light-transmissive Member 50

As illustrated in FIG. 4, the light-emitting device 1000 includes the light-transmissive member 50. The light-transmissive member 50 is a member that has transmissivity for light emitted by the light source 20. The light-transmissive member 50 covers side surfaces of the light source 20. For example, light transmittance of the light-transmissive member 50 at the emission peak wavelength of the light source 20 is preferably 60% or more, and more preferably 80% or more. This facilitates improvement in the light extraction efficiency of the light-emitting device 1000. As illustrated in FIG. 4, the light-transmissive member 50 is preferably in contact with the lateral surfaces of the light source 20. This configuration facilitates light from the light source 20 entering the light-transmissive member 50. A material for the light-transmissive member 50 may be, for example, thermosetting resin such as an epoxy resin or a silicone resin.

In the present embodiment, the light-transmissive member 50 covers at least a portion of the upper surface of the light source 20. With the light-transmissive member 50 covering at least the portion of the upper surface of the light source 20, the luminance of a region directly above the light source 20 can be easily adjusted. For example, by adjusting a thickness of the portion of the light-transmissive member 50 which covers the upper surface of the light source 20, the luminance of the region directly above the light source 20 can be adjusted. This configuration facilitates adjustment of the luminance, and thus facilitates reduction of luminance unevenness in the light-emitting device 1000. With the light-transmissive member 50 covering the entire upper surface of the light source 20, the luminance of the region directly above the light source 20 can be further easily adjusted. Alternatively, the entire upper surface of the light source 20 may be exposed without being covered by the light-transmissive member 50. This configuration facilitates size reduction of the light-emitting device 1000 in the vertical direction.

In the present embodiment, as illustrated in FIG. 2, the light-transmissive member 50 is demarcated into a plurality of segments by partition grooves 50G. Each of the segments defined by the partition grooves 50G is referred to as a light-emitting region 100A. In the present embodiment, a first light-transmissive part 51S, a second light-transmissive part 52S, a third light-transmissive part 53S, and a fourth light-transmissive part 54S constitute different light-emitting regions 100A, each defined by the partition grooves 50G. The light-transmissive member 50 includes the first light-transmissive part 51S, the second light-transmissive part 52S, the third light-transmissive part 53S, and the fourth light-transmissive part 54S. A single light-emitting region 100A can be used as a unit of driving of local dimming. The number of light-emitting regions 100A constituting the light-emitting device 1000 is not particularly limited. For example, the light-emitting device 1000 may include a single light-emitting region 100A, or the light-emitting device 1000 may include a plurality of light-emitting regions 100A. By arranging a plurality of light-emitting devices 1000, a wider-area light-emitting module can be constituted. Each partition groove 50G may be filled with a member that is reflective for light emitted from the light source 20. This configuration enables improvement in the contrast between light-emitting regions in a light-emitting state and light-emitting regions in a non-light-emitting state. However, each partition groove 50G in a light-emitting module is not necessarily filled with a member that is reflective for light emitted from the light source 20.

When the light-emitting device 1000 includes a plurality of light-emitting regions 100A, the light-emitting regions 100A may have the same or different shapes in a top view. For example, when the light-transmissive member 50 has a circular shape in a top view, as illustrated in FIG. 1, some light-emitting regions 100A positioned near the outer circumference and other light-emitting regions 100A positioned near the center of the light-emitting device 1000 may have different shapes.

In the present embodiment, as illustrated in FIG. 2, the light-transmissive member 50 is provided with the grid-shaped partition grooves 50G that include a first partition groove 51G extending in the Y-direction and a second partition groove 52G extending in the X-direction. The first partition groove 51G extends in the Y direction between the first light-transmissive part 51S and the second light-transmissive part 52S. The second partition groove 52G extends in the X direction between the first light-transmissive part 51S and the third light-transmissive part 53S. Alternatively, each partition groove 50G may be inclined with respect to both the X direction and the Y direction.

Each partition groove 50G preferably extends from the upper surface of the light-transmissive member 50 to the lower surface thereof. Thus, the light-transmissive member 50 can be separated into a plurality of segments. This configuration facilitates reduction of warpage of the light-transmissive member 50 and/or the support body 10 due to a difference in thermal expansion coefficient between the light-transmissive member 50 and the support body 10. Alternatively, each partition groove 50G may be a recess that has an opening only in an upper surface of the light-transmissive member 50 or only in a lower surface of the light-transmissive member 50. When each partition groove 50G is such a recess, the partition groove 50G has a bottom surface formed by the light-transmissive member 50. Both of opposing inner lateral surfaces of each partition groove 50G may be surfaces parallel to the Z direction or surfaces inclined with respect to the Z direction. When inclined with respect to the Z direction, the lateral surfaces of each partition groove 50G may be farther from or closer to each other toward the bottom. An outer surface of each light-transmissive member 50 which defines the outer circumference of the light-emitting device 1000 may be a surface parallel to the Z direction or a surface inclined with respect to the Z direction. Alternatively, if a light-emitting device does not include such a light-transmissive member, light-emitting regions may be defined by reflective members surrounding light sources.

As illustrated in FIG. 4, the light-transmissive member 50 preferably has one or more holes (referred to below as light-transmissive holes 50A) that have openings in the upper surface and/or lower surface of the light-transmissive member 50. In the present embodiment, each light-transmissive hole 50A is a recess having an opening only in the upper surface of the light-transmissive member 50. Alternatively, each light-transmissive hole 50A may be a recess having an opening only in the lower surface of the light-transmissive member 50 or a through hole that extend from the upper surface to the lower surface of the light-transmissive member 50. With the light-transmissive member 50 having the light-transmissive holes 50A, a surface area of the light-transmissive member 50 can be increased. As a result, the amount of light extracted from the surface of the light-transmissive member 50 to an exterior of the light-transmissive member 50 can be increased. This configuration facilitates adjustment of the luminance of the light-emitting device 1000, and thus facilitates reduction of luminance unevenness in the light-emitting device 1000. A depth of each recess in the vertical direction is, for example, at least 0.1 times the maximum length of the light-transmissive member 50 in the vertical direction. The light-transmissive member 50 may have a single light-transmissive hole 50A or a plurality of light-transmissive holes 50A.

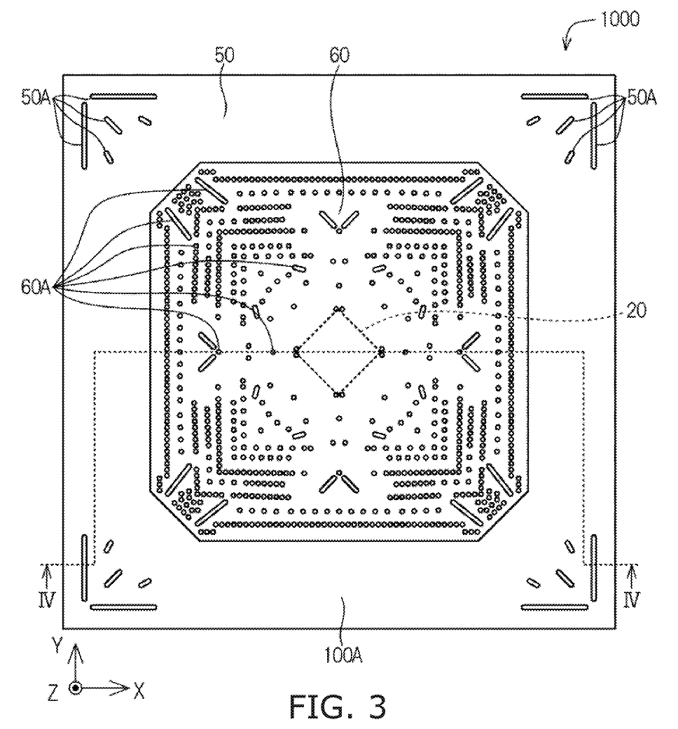

Each light-transmissive hole 50A has any appropriate shape in a plan view. As illustrated in FIG. 3, each light-transmissive hole 50A may have a linear segment in a top view. The term “linear shape” as used in the present specification includes a straight, curved, angled, or other shape. In a top view, the shape of each light-transmissive hole 50A may be formed of two linear segments extending in different directions, such as a V- or L-shape. Alternatively, each light-transmissive hole 50A may have a circular shape, an elliptic shape, or a polygonal shape such as a triangular shape, a quadrilateral shape, a hexagonal shape, or an octagonal shape, in a top view.

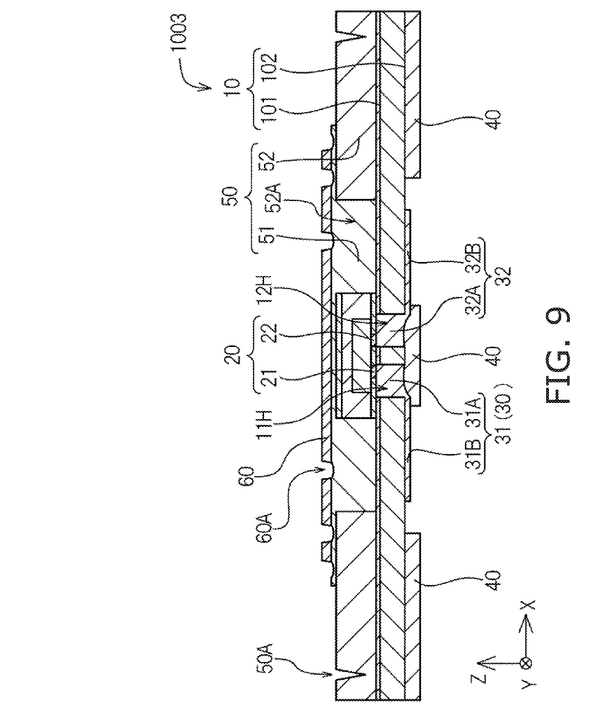

As in a light-emitting device 1003 illustrated in FIG. 9, a light-transmissive member 50 may include a first light-transmissive member 51 and a second light-transmissive member 52. The second light-transmissive member 52 includes a through hole (referred to below as a light-transmission through hole 52A). The light-transmission through hole 52A extends from the upper surface of the second light-transmissive member 52 to the lower surface thereof. A light source 20 and the first light-transmissive member 51 are positioned within the light-transmission through hole 52A. The first light-transmissive member 51 is in contact with both the light source 20 and the light-transmissive member 50. The first light-transmissive member 51 and the second light-transmissive member 52 may be made of the same material or different materials. For example, the first light-transmissive member 51 may be made of thermosetting resin such as an epoxy resin or a silicone resin, and the second light-transmissive member 52 may be made of thermoplastic resin such as a polycarbonate resin.

### Light Adjustment Member 60

As illustrated in FIGS. 3 and 4, the light-emitting device 1000 includes a light adjustment member 60. The light adjustment member 60 has both light reflectivity and transmissivity for light emitted by the light source 20. A portion of the light emitted from the light source 20 is reflected by the light adjustment member 60, and another portion is transmitted through the light adjustment member 60. Light transmittance of the light adjustment member 60 at the emission peak wavelength of the light source 20 is lower than the light transmittance of the light-transmissive member 50 at the emission peak wavelength of the light source 20. For example, the light transmittance of the light adjustment member 60 at the emission peak wavelength of the light source 20 is preferably in the range of 1to 50%, and more preferably in the range of 3to 30%. The light adjustment member 60 may be formed of a single layer or a plurality of layers stacked in the vertical direction. The light adjustment member 60 can be formed of, for example, a resin member and a reflector included in the resin member. The resin member in the light adjustment member 60 may be made of the same material as the resin member in the support body 10. The reflector in the light adjustment member 60 may be made of the same material as the reflector in the support body 10. However, the light-emitting device 1000 does not necessarily include the light adjustment member 60.

In the present embodiment, as illustrated in FIG. 4, the light adjustment member 60 is positioned above the light source 20. In a top view, a portion of the light adjustment member 60 overlaps the light source 20. In the overlapping area, the light adjustment member 60 is positioned above the light source 20. With the light adjustment member 60 located above the light source 20, the region directly above the light source 20 can be suppressed from being too bright.

The light adjustment member 60 preferably has one or more holes (referred to below as light adjustment holes 60A) each having an opening/openings in the upper surface and/or lower surface of the light adjustment member 60. In the present embodiment, each light adjustment hole 60A is a through hole that extends from the upper surface of the light adjustment member 60 to the lower surface thereof. Alternatively, each light adjustment hole 60A may be a recess that has an opening only in the upper surface of the light adjustment member 60 or only in the lower surface of the light adjustment member 60. With the light adjustment member 60 having the light adjustment holes 60A, the luminance can be easily adjusted within the region directly above the light adjustment member 60. For example, by changing the sizes or locations of the light adjustment holes 60A, the amount of light from the light source 20 that is blocked by the light adjustment member 60 can be easily adjusted. This configuration facilitates reduction of luminance unevenness in the light-emitting device 1000 because the luminance within the region directly above the light adjustment member 60 can be easily adjusted.

The light adjustment holes 60A in the light adjustment member 60 are preferably spaced apart from the light source 20 in a top view. This configuration inhibits the region directly above the light source 20 from being excessively bright. The shape of each light adjustment hole 60A in plan view is not particularly limited. As illustrated in FIG. 3, the shape of the light adjustment holes 60A in a top view may include a linear segment. The shape of the light adjustment hole 60A may be formed of two linear segments extending in different directions, such as a V- or L-shape, in top view. Alternatively, each light adjustment hole 60A may have a circular shape, an elliptic shape , or a polygonal shape such as a triangular shape, a quadrilateral shape, a hexagonal shape, or an octagonal shape, in a top view.

The light adjustment holes 60A are preferably aligned with the respective light-transmissive holes 50A in the vertical direction. In other words, the light adjustment holes 60A are preferably aligned with the respective light-transmissive holes 50A in a top view. This configuration allows for inhibiting light emitted from the light-transmissive holes 50A toward the exterior of the light-emitting device 1000 from being blocked by the light adjustment member 60. This configuration facilitates adjustment in the luminance of the light-emitting device 1000 and thus facilitates reduction of luminance unevenness of the light-emitting device 1000. Aligning the light adjustment holes 60A with the respective light-transmissive holes 50A in the vertical direction facilitates formation of both the light adjustment holes 60A and the light-transmissive holes 50A. For example, the light adjustment holes 60A and the light-transmissive holes 50A can be formed simultaneously by using a laser or a blade.

### Second Embodiment

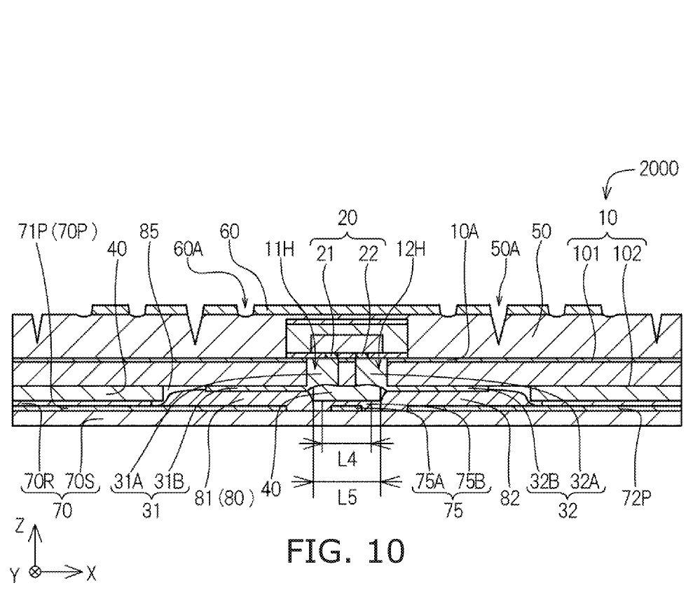

Next, a light-emitting module 2000 according to a second embodiment will be described below with reference to FIGS. 10 to 19. The light-emitting module 2000 according to the second embodiment includes the light-emitting device 1000 according to the first embodiment, a wiring substrate 70, and a conductor 80. A light-emitting module may include a single light-emitting device or a plurality of light-emitting devices. For example, a light-emitting module may include a plurality of light-emitting devices positioned on or above a single wiring substrate. Components constituting the light-emitting module 2000 will be described below in detail. The same term or reference numeral as previously described represents the same member or a similar member or configuration, and its detailed description will be omitted as appropriate.

### Wiring Substrate 70

The wiring substrate 70 is a member employed to supply power to the light sources 20. The wiring substrate 70 includes a base member 70S having an insulation property and a plurality of wiring members 70P each having a conductive property. The base member 70S may be a rigid substrate or a flexible substrate. Examples of a material for the base member 70S include an epoxy resin, a bismaleimide triazine (BT) resin, and a polyimide resin. In order to reduce the size of the light-emitting module 2000 in the vertical direction the base member 70S is preferably a flexible substrate. The base member 70S may be formed of a single layer or a plurality of layers stacked in the vertical direction. For example, the base member 70S may be a single-layered flexible substrate or a stacked body formed of a plurality of rigid substrates.

As illustrated in FIG. 10, the wiring substrate 70 includes the wiring members 70P disposed on an upper surface of the base member 70S. In this case, the wiring substrate 70 may include two or more wiring members 70P. Each wiring member 70P is made of a metal film such as a copper film. Furthermore, each wiring member 70P can be formed by a known method such as electrolytic plating, electroless plating, vapor deposition, sputtering. In the present embodiment, the wiring members 70P include a first wiring member 71P and a second wiring member 72P. In the present embodiment, the wiring substrate 70 further includes a covering layer 70R. At least a portion of the first wiring member 71P is exposed without being covered by the covering layer 70R. Likewise, at least a portion of the second wiring member 72P is exposed without being covered by the covering layer 70R. The covering layer 70R may be formed using a resist, for example. A material for the resist may be an acrylic resin, for example.

### Conductor 80

The conductor 80 is a conductive member configured to supply power to the light sources 20. The material of the conductor 80 is not particularly limited. The material for the conductor 80 can be the same as the material for the conductive member 30. The conductor 80 may contain a thermosetting resin, and the support body 10 may contain a thermoplastic resin. In this case, it is preferable that a melting point of the thermoplastic resin in the support body 10 be higher than a curing temperature of the thermosetting resin in the conductor 80. Accordingly, a decrease in the light reflectivity of the support body 10 can be suppressed, because the thermoplastic resin in the support body 10 does not melt even when the thermosetting resin of the conductor 80 reaches the curing temperature. The thermosetting resin in the conductor 80 can be an epoxy resin, and the thermoplastic resin in the support body 10 can be made of polyethylene terephthalate.

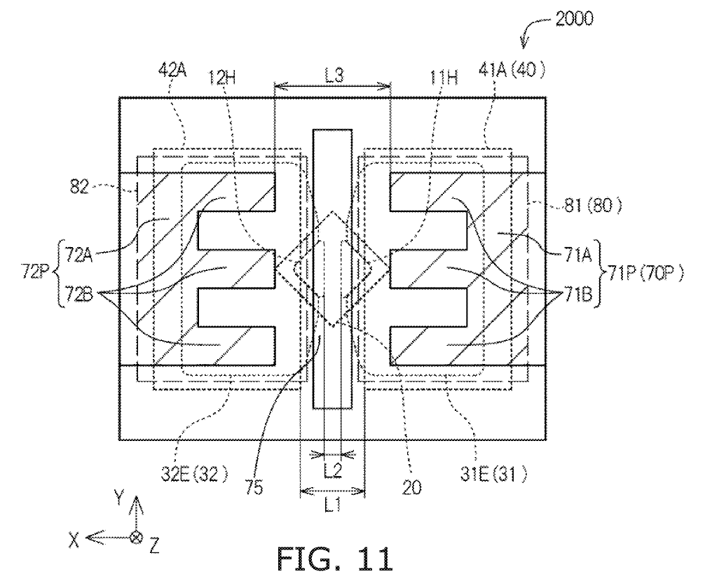

As viewed from the second surface side, as illustrated in FIG. 11, the distance L1, which is the shortest distance from the first exposed conductive region 31E to the second exposed conductive region 32E is preferably greater than the distance L2, which is the shortest distance from the first through hole 11H to the second through hole 12H. In other words, as viewed from the second surface side, the distance L1, which is the shortest distance from the region of the first conductive member 31 exposed without being covered by the insulating member 40 to the region of the second conductive member 32 exposed without being covered by the insulating member 40, is preferably greater than the distance L2, which is the shortest distance from the first through hole 11H to the second through hole 12H. With this configuration, the first conductor 81 and a second conductor 82 are less likely to come into contact with each other when the light-emitting device 1000 is mounted on the wiring substrate 70. This can reduce short-circuiting of the light-emitting module 2000. As a result, the reliability of the light-emitting module 2000 can be improved.

As viewed from the second surface side, as illustrated in FIG. 11, a distance L3 is preferably greater than the distance L1. Here, the distance L3 is the shortest distance from a portion of the first wiring member 71P that overlaps the first conductor 81 to a portion of the second wiring member 72P that overlaps the second conductor 82, and the distance L1 is the shortest distance from the first exposed conductive region 31E to the second exposed conductive region 32E. In other words, as viewed from the second surface side, the distance L3, which is the shortest distance from the portion of the first wiring member 71P that overlaps the first conductor 81 to the portion of the second wiring member 72P that overlaps the second conductor 82 is preferably greater than the distance L1, which is the shortest distance from the region of the first conductive member 31 exposed without being covered by the insulating member 40 to the portion of the second conductive member 32 exposed without being covered by the insulating member. This configuration facilitates a reduction in contact between the first conductor 81 and the second conductor 82. This can reduce short-circuiting of the light-emitting module 2000. As a result, the reliability of the light-emitting module 2000 can be improved. In FIGS. 11, 12, and 13, an area in which the first wiring member 71P overlaps the first conductor 81 and an area in which the second wiring member 72P overlaps the second conductor 82 are hatched with diagonal lines running from the lower left to the upper right.

In the present embodiment, as illustrated in FIG. 11, the first wiring member 71P includes a first wiring main portion 71A and a plurality of first wiring extending portions 71B, each of which extends from the first wiring main portion 71A. The light source 20 and the first wiring main portion 71A are positioned side by side in the first direction (X direction). The first wiring main portion 71A is positioned on the −X-side of the light source 20. The plurality of first wiring extending portions 71B are positioned between the light source 20 and the first wiring main portion 71A in the first direction. Each first wiring extending portion 71B extends from the first wiring main portion 71A toward the light source 20, namely, in the first direction. With the first wiring member 71P including the plurality of first wiring extending portions 71B, a contact area between the first wiring member 71P and the first conductor 81 can be easily increased, which allows for reducing lighting failures due to poor contact between the first wiring member 71P and the first conductor 81. As a result, the reliability of the light-emitting module 2000 can be improved. The first conductor 81 is preferably in contact with the first wiring main portion 71A and the plurality of first wiring extending portions 71B. This configuration facilitates an increase in a contact area between the first wiring member 71P and the first conductor 81. The number of the first wiring extending portions 71B is not particularly limited. For example, two, three, or four or more first wiring extending portions 71B may be provided.

In the present embodiment, the second wiring member 72P includes a second wiring main portion 72A and a plurality of second wiring extending portions 72B, each of which extends from the second wiring main portion 72A. The light source 20 and the second wiring main portion 72A are arranged in the first direction. The second wiring main portion 72A is positioned on the +X-side of the light source 20. The plurality of second wiring extending portions 72B are positioned between the light source 20 and the second wiring main portion 72A in the first direction. Each second wiring extending portion 72B extends from the second wiring main portion 72A toward the light source 20, namely, in the first direction. With the second wiring member 72P including the plurality of second wiring extending portions 72B, a contact area between the second wiring member 72P and the second conductor 82 is easily increased, which allows for reducing lighting failures due to poor contact between the second wiring member 72P and the second conductor 82. As a result, the reliability of the light-emitting module 2000 can be improved. The second conductor 82 is preferably in contact with the second wiring main portion 72A and the plurality of second wiring extending portions 72B. This configuration facilitates an increase in a contact area between the second wiring member 72P and the second conductor 82. The number of the second wiring extending portions 72B is not particularly limited. For example, two, three, or four or more second wiring extending portions 72B may be provided.

As illustrated in FIG. 10, it is preferable that a gas 85 such as nitrogen or oxygen be present between the support body 10 and the wiring substrate 70. A refractive index of gases such as nitrogen and oxygen is generally lower than a refractive index of resin members. For this reason, when a portion of light from the light source 20 enters the support body 10, a portion of the light is likely to be totally reflected at an interface between the support body 10 and the gas 85. Accordingly, the gas 85 present between the support body 10 and the wiring substrate 70 facilitates total reflection of the light traveling downward from the light source 20. As a result, this configuration facilitates improvement in the light extraction efficiency of the light-emitting module 2000.

In the present embodiment, as illustrated in FIGS. 10 and 11, the wiring substrate 70 includes a projection 75 having an insulating property. As viewed from the second surface side, the projection 75 is positioned between a portion of the first wiring member 71P that overlaps the first conductor 81 and a portion of the second wiring member 72P that overlaps the second conductor 82. With the wiring substrate 70 including the projection 75, the first conductor 81 and the second conductor 82 are less likely to come into contact with each other. This can reduce short-circuiting of the light-emitting module 2000. As a result, the reliability of the light-emitting module 2000 can be improved. The insulating member 40 is preferably in contact with the projection 75. With this structure, heat generated by the light source 20 is likely to be transferred through the insulating member 40 to the projection 75, which is a portion of the wiring substrate 70. Consequently, this facilitates improvement in the heat dissipation performance of the light-emitting module 2000.

A thickness of the projection 75 is preferably greater than a thickness of the first wiring member 71P. This configuration can further reduce contact between the first conductor 81 and the second conductor 82. Likewise, the thickness of the projection 75 is preferably greater than a thickness of the second wiring member 72P. In the present specification, the thickness of the projection 75 is defined as the maximum distance in the vertical direction between the upper surface of the base member 70S and the upper surface of the projection 75. The thickness of the first wiring member 71P is defined as the maximum distance in the vertical direction between the upper surface of the base member 70S and the upper surface of the first wiring member 71P. The thickness of the second wiring member 72P is defined as the maximum distance in the vertical direction between the upper surface of the base member 70S and the upper surface of the second wiring member 72P.

The projection 75 preferably includes a metal member 75A and an insulating layer 75B covering the metal member 75A. With the projection 75 including the metal member 75A, improvement in the heat dissipation performance of the light-emitting module 2000 can be facilitated because metal members generally have higher thermal conductivity than insulating members such as resins. A thickness of the metal member 75A is preferably between 0.9 and 1.1 times the thickness of the first wiring member 71P. This configuration can facilitate formation of the first wiring member 71P, the second wiring member 72P, and a portion of the projection 75. For example, by forming a resist mask on a metal film positioned on the base member 70S and then etching the metal film, the first wiring member 71P, the second wiring member 72P, and the portion of the projection 75 can be formed in the same step. The metal member 75A of the projection 75 may be made of, for example, copper, aluminum, gold, silver, iron, nickel, or an alloy of these metals. The insulating layer 75B of the projection 75 may be made of, for example, a resist similar to that used for the covering layer 70R. In the present embodiment, the insulating layer 75B covering the upper and side surfaces of the metal member 75A prevents the first conductor 81 and the second conductor 82 from being in contact with the metal member 75A.

In a cross-section passing through a first electrode 21 and a second electrode 22, as illustrated in FIG. 10, a length L4 is preferably shorter than a length L5, where the length L4 is the maximum length of the projection 75 in the first direction, and the length L5 is the maximum length, in the first direction, of a portion of the insulating member 40 positioned directly below the light source 20. This structure allows for enlarging a space defined by the light-emitting device 1000 and the wiring substrate 70, allowing a volume of the first conductor 81 and/or the second conductor 82 to increase. As a result, heat generated by the light source 20 is likely to be transferred to the wiring substrate 70 through the first conductor 81 and/or the second conductor 82, thereby allowing for improving the heat dissipation performance of the light-emitting module 2000. It should be noted that a portion of the insulating member 40 positioned directly below the light source 20 refers to a portion of the insulating member 40 that overlaps the light source 20 as viewed from the second surface side.

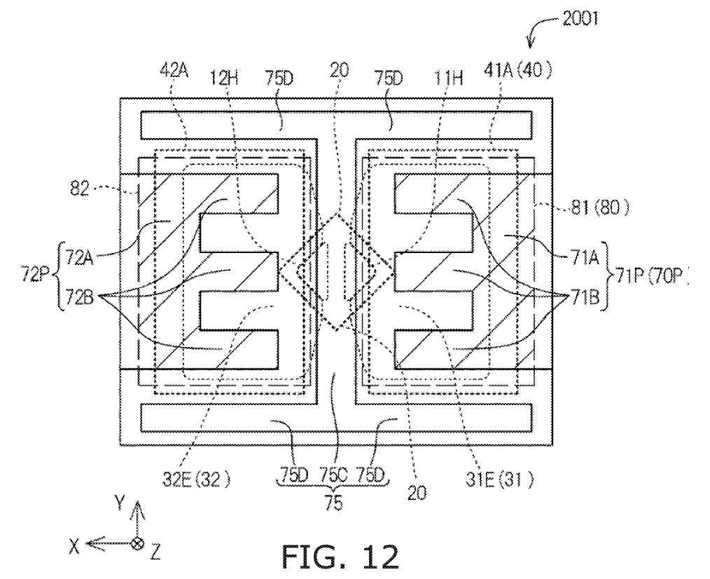

As in a light-emitting module 2001 illustrated in FIG. 12, a projection 75 may include a projection main portion 75C and a plurality of projection extending portions 75D each of which extends from the projection main portion 75C. In the present embodiment, two projection extending portions 75D extend from respective ends of the projection main portion 75C. As viewed from the second surface side, the projection main portion 75C is positioned between the portion of the first wiring member 71P that overlaps the first conductor 81 and the portion of the second wiring member 72P that overlaps the second conductor 82. The portion of the first wiring member 71P that overlaps the first conductor 81 is preferably positioned in the second direction (Y direction) between the two projection extending portions 75D. This configuration reduces contact between the first conductor 81 and the second conductor 82, allowing for reducing short-circuiting of the light-emitting module 2001. As a result, the reliability of the light-emitting module 2001 can be improved. Moreover, the portion of the second wiring member 72P that overlaps the second conductor 82 is preferably positioned in the second direction between the two projection extending portions 75D. This configuration reduces contact between the first conductor 81 and the second conductor 82.

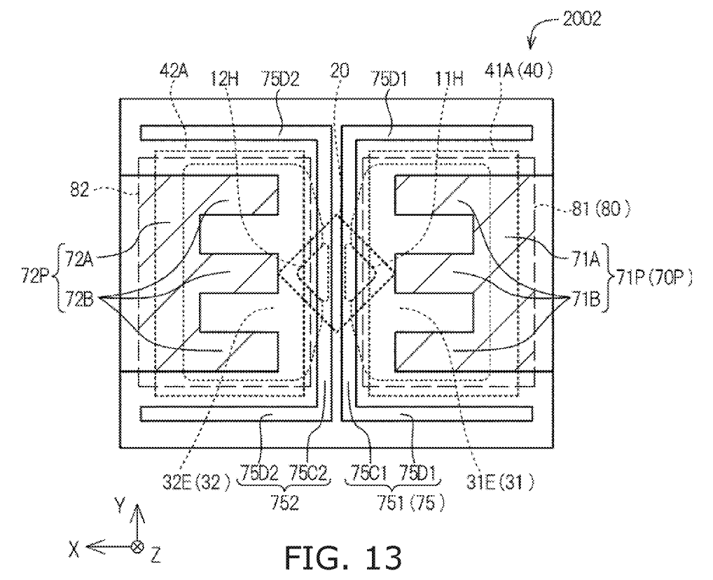

As in a light-emitting module 2002 illustrated in FIG. 13, a projection 75 includes a first projection 751 and a second projection 752. In the present embodiment, the first projection 751 includes a first projection main portion 75C1 and two first projection extending portions 75D1 each of which extends from the first projection main portion 75C1. As viewed from the second surface side, the first projection main portion 75C1 of the first projection 751 is positioned between a portion of the first wiring member 71P that overlaps the first conductor 81 and a portion of the second wiring member 72P that overlaps the second conductor 82. The portion of the first wiring member 71P that overlaps the first conductor 81 is positioned in the second direction between the two first projection extending portions 75D1 of the first projection 751. This configuration reduces contact between the first conductor 81 and the second conductor 82. In the present embodiment, the second projection 752 includes a second projection main portion 75C2 and two second projection extending portions 75D2 each of which extends from the second projection main portion 75C2. As viewed from the second surface side, the second projection main portion 75C2 of the second projection 752 is positioned between a portion of the first wiring member 71P that overlaps the first conductor 81 and a portion of the second wiring member 72P that overlaps the second conductor 82. The portion of the second wiring member 72P that overlaps the second conductor 82 is positioned in the second direction between the two second projection extending portions 75D2 of the second projection 752. This configuration reduces contact between the first conductor 81 and the second conductor 82.

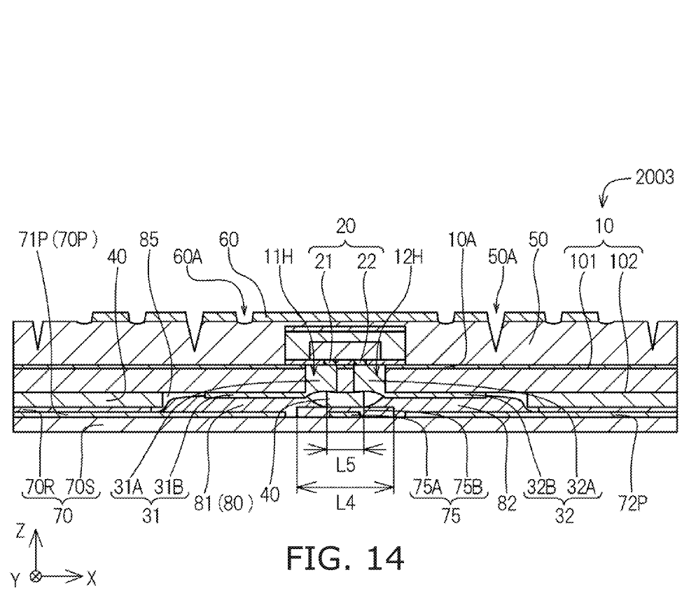

As in a light-emitting module 2003 illustrated in FIG. 14, in the cross-section passing through the first electrode 21 and the second electrode 22, the length L4, which is the maximum length of the projection 75 in the first direction, may be greater than the length L5, which is the maximum length, in the first direction, of the portion of the insulating member 40 positioned directly below the light source 20. With the projection 75, the first conductor 81 and the second conductor 82 are less likely to come into contact with each other.

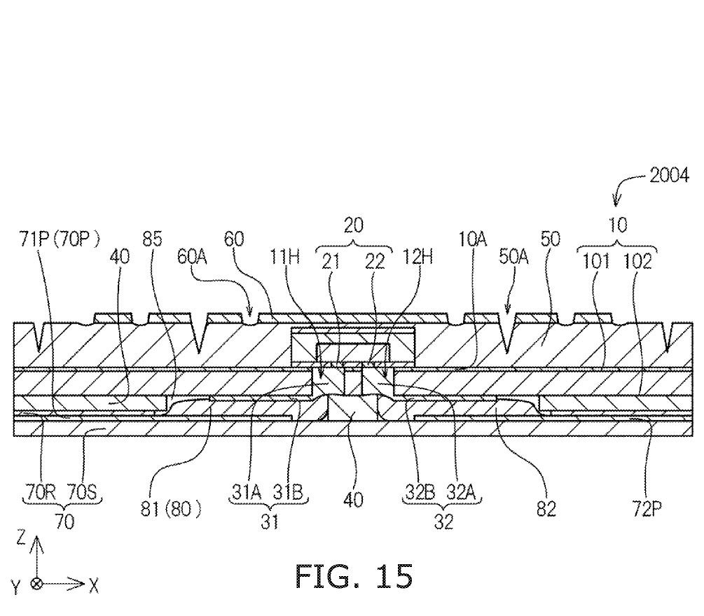

The wiring substrate 70 does not necessarily include the projection 75. As in a light-emitting module 2004 illustrated in FIG. 15, in the cross-section passing through the first electrode 21 and the second electrode 22, the portion of an insulating member 40 positioned directly below the light source 20 may be in contact with the upper surface of the base member 70S in the wiring substrate 70. This configuration facilitates improvement in the adhesive strength between the insulating member 40 and the wiring substrate 70 when the insulating member 40 exhibits an adhesive property. Moreover, in the cross-section passing through the first electrode 21 and the second electrode 22, a thickness of the portion of the insulating member 40 positioned directly below the light source 20 may be greater than a thickness of a portion of the insulating member 40 that is not positioned directly below the light source 20. This configuration facilitates contact of the portion of the insulating member 40 positioned directly below the light source 20 with the upper surface of the base member 70S in the wiring substrate 70.

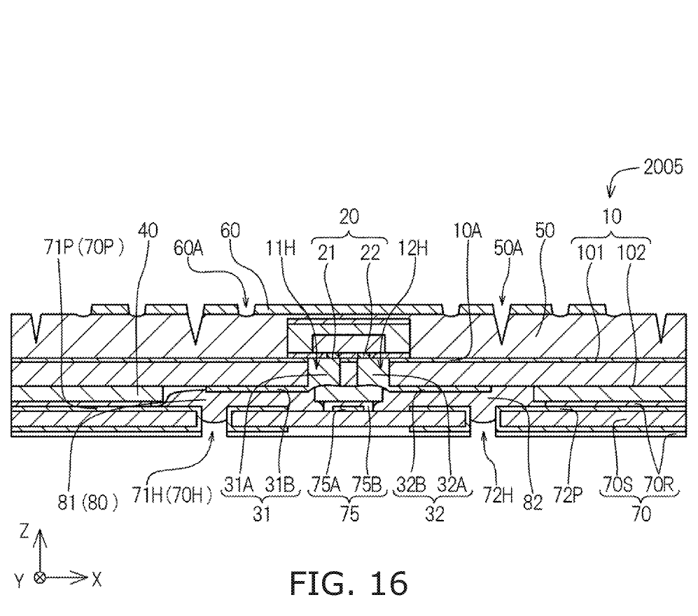

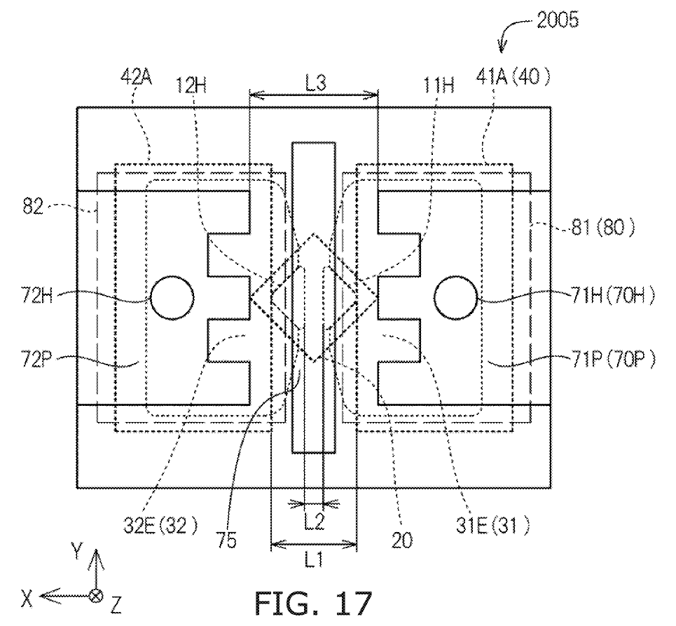

As in a light-emitting module 2005 illustrated in FIGS. 16 and 17, the wiring substrate 70 may include a plurality of through holes (referred to as wiring through holes 70H). As viewed from the second surface side, the wiring through holes 70H do not overlap the insulating member 40. In the present embodiment, the wiring through holes 70H include a first wiring through hole 71H and a second wiring through hole 72H. The first wiring through hole 71H is positioned within the first aperture 41A in the insulating member 40, as viewed from the second surface side. Likewise, the second wiring through hole 72H is positioned within the second aperture 42A in the insulating member 40, as viewed from the second surface side. With the wiring substrate 70 having the first wiring through hole 71H, a gas easily escapes to the exterior of the light-emitting module 2005 through the first wiring through hole 71H even when the gas is present between the support body 10 and the wiring substrate 70. This configuration facilitates reduction of void formation inside the first conductor 81. As a result, the reliability of the light-emitting module 2005 can be improved. Likewise, providing the wiring substrate 70 with the second wiring through hole 72H allows the gas to escape to the exterior of the light-emitting module 2005 through the second wiring through hole 72H even when gas is present between the support body 10 and the wiring substrate 70.

As illustrated in FIG. 16, a portion of the first conductor 81 is preferably positioned within the first wiring through hole 71H. This configuration allows a volume of the first conductor 81 to increase. As a result, this facilitates improvement in the heat dissipation performance of the light-emitting module 2005. Likewise, a portion of a second conductor 82 is preferably positioned within the second wiring through hole 72H, allowing a volume of the second conductor 82 to increase. At least a portion of an inner surface of the first wiring through hole 71H is preferably formed of the first wiring member 71P. This configuration facilitates an increase in a contact area between the first wiring member 71P and the first conductor 81, thereby reducing lighting failures due to poor contact between the first wiring member 71P and the first conductor 81. As a result, the reliability of the light-emitting module 2005 can be improved. Likewise, at least a portion of an inner surface of the second wiring through hole 72H is preferably formed of the second wiring member 72P. This configuration facilitates an increase in a contact area between the second wiring member 72P and the second conductor 82. Furthermore, the first wiring through hole 71H and/or the second wiring through hole 72H may be formed only in the base member 70S. Moreover, the first conductor 81 may be spaced apart from the first wiring through hole 71H, as viewed from the second surface side. Likewise, the second conductor 82 may be spaced apart from the second wiring through hole 72H, as viewed from the second surface side.

As illustrated in FIG. 11, the light source 20 preferably overlaps the first conductor 81, as viewed from the second surface side. This configuration facilitates heat transfer from the light source 20 to the wiring substrate 70 through the first conductor 81, thereby improving the heat dissipation performance of the light-emitting module 2000. As a result, the reliability of the light-emitting module 2000 can be improved. Likewise, the light source 20 preferably overlaps the second conductor 82, as viewed from the second surface side. This configuration also facilitates heat transfer from the light source 20 to the wiring substrate 70 through the second conductor 82.

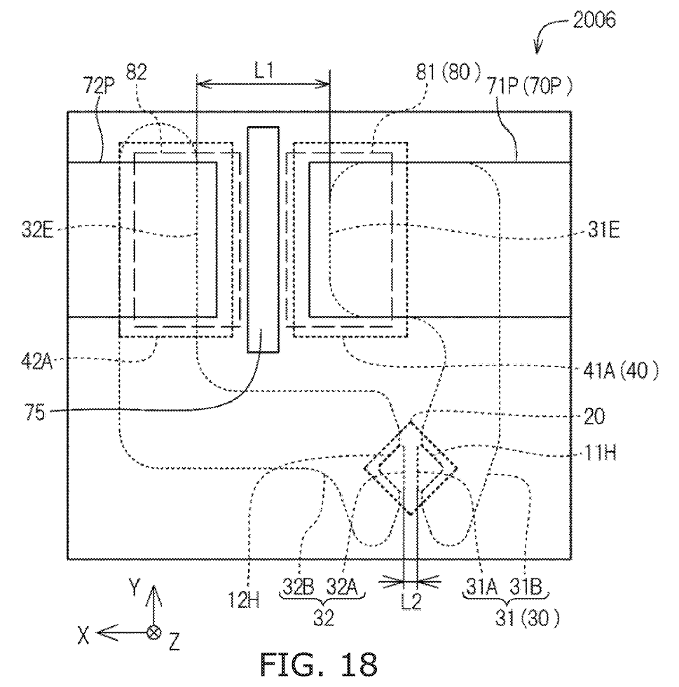

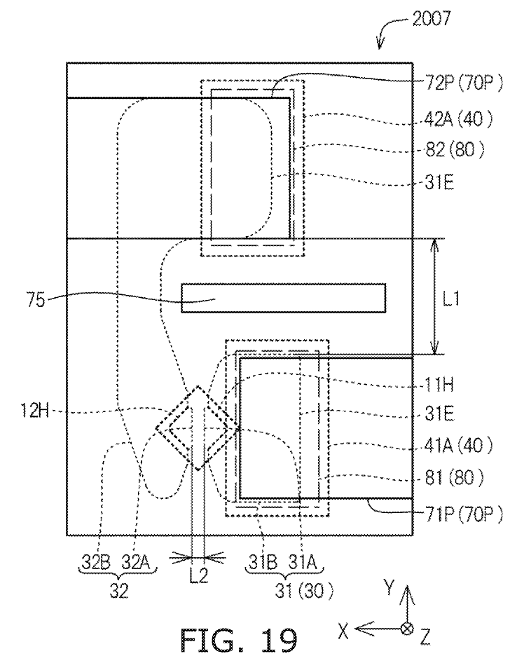

As in a light-emitting module 2006 illustrated in FIG. 18, the first conductor 81 and the second conductor 82 do not necessarily overlap the light source 20, as viewed from the second surface side. This configuration does not restrict locations where the first conductor 81 and the second conductor 82 are formed, thereby improving the design flexibility of the light-emitting module 2006. As in a light-emitting module 2007 illustrated in FIG. 19, the first conductor 81 may overlap the light source 20, but the second conductor 82 does not necessarily overlap the light source 20, as viewed from the second surface side. The configuration in which the light source 20 overlaps the first conductor 81 as viewed from the second surface side facilitates heat transfer from the light source 20 to the wiring substrate 70 through the first conductor 81. The configuration in which the light source 20 does not overlap the second conductor 82 as viewed from the second surface side does not restrict locations where the second conductor 82 can be formed, thereby improving the design flexibility of the light-emitting module 2007. Alternatively, the second conductor 82 may overlap the light source 20, but the first conductor 81 does not necessarily overlap the light source 20, as viewed from the second surface side.

The embodiments of the present invention has been described above referring to specific examples. However, the present invention is not limited to these specific examples. For example, modifications obtained by adding or removing some components or steps to or from each of the embodiments described above are also encompassed by the present invention. In addition, two or more of the foregoing embodiments can be combined together.

Embodiments of the present invention are useful for various illumination light sources, on-vehicle light sources, display light sources, and other types of light sources. Embodiments of the present invention are advantageously applicable, especially to backlight units adapted for liquid crystal display devices.

What is claimed is:

1. A light-emitting device comprising:
a support body having a first through hole and a second through hole that extend from a first surface to a second surface opposite to the first surface;
a light source mounted on the support body on a side of the first surface and including a first electrode and a second electrode;
a first conductive member electrically connected to the first electrode, the first conductive member including a first part within the first through hole and a second part on a side of the second surface, the second part being continuous with the first part;
a second conductive member electrically connected to the second electrode, the second conductive member including a third part within the second through hole and a fourth part on the side of the second surface, the fourth part being continuous with the third part; and
an insulating member disposed on the side of the second surface, the insulating member overlapping at least a portion of the first part and at least a portion of the third part in a view from the side of the second surface, wherein
a shortest distance from an exposed region of the first conductive member that is exposed to the side of the second surface and uncovered by the insulating member to an exposed region of the second conductive member that is exposed to the side of the second surface and uncovered by the insulating member is greater than a shortest distance from the first through hole to the second through hole.

2. The light-emitting device according to claim 1, wherein a portion of the first part is exposed to the side of the second surface in the view from the side of the second surface.

3. The light-emitting device according to claim 1, wherein
the first electrode and the second electrode are arranged in a first direction,
the insulating member includes a first aperture,
the exposed region of the first conductive member is exposed to the side of the second surface through the first aperture, and
a maximum length of the first aperture in the first direction is greater than a maximum length of the light source in the first direction.

4. The light-emitting device according to claim 3, wherein a maximum length of the first aperture in a second direction orthogonal to the first direction is greater than a maximum length of the light source in the second direction.

5. The light-emitting device according to claim 3, wherein
the insulating member includes a second aperture,
the exposed region of the second conductive member is exposed to the side of the second surface through the second aperture, and
a maximum length of the second aperture in the first direction is greater than a maximum length of the light source in the first direction.

6. The light-emitting device according to claim 5, wherein
a maximum length of the first aperture in a second direction orthogonal to the first direction is greater than a maximum length of the light source in the second direction, and
a maximum length of the second aperture in the second direction is greater than a maximum length of the light source in the second direction.

7. The light-emitting device according to claim 1, wherein
the first electrode and the second electrode are arranged in a first direction, and
a maximum length of the exposed region of the first conductive member in the first direction is greater than a maximum length of the light source in the first direction.

8. The light-emitting device according to claim 1, wherein
the first electrode and the second electrode are arranged in a first direction, and
in the view from the side of the second surface, the shortest distance from the exposed region of the first conductive member to the exposed region of the second conductive member is less than a maximum length of the light source in the first direction.

9. The light-emitting device according to claim 1, wherein the insulating member entirely overlaps the first part of the first conductive member and the third part of the second conductive member in the view from the side of the second surface.

10. The light-emitting device according to claim 1, wherein
a mounted surface of the light source that faces the support body has a rectangular shape, and
the first conductive member and the second conductive member are arranged in a diagonal direction of the mounting surface of the light source.

11. A light-emitting module comprising:
the light-emitting device according to claim 1:
a wiring substrate electrically connected to the light-emitting device, the wiring substate including a first wiring member and a second wiring member;
a first conductor electrically connecting the first conductive member to the first wiring member; and
a second conductor electrically connecting the second conductive member to the second wiring member.

12. The light-emitting module according to claim 11, wherein in the view from the side of the second surface, a shortest distance from an overlapping region of the first wiring member that overlaps the first conductor to an overlapping region of the second wiring member that overlaps the second conductor is greater than a shortest distance from the exposed region of the first conductive member to the exposed region of the second conductive member.

13. The light-emitting module according to claim 11, wherein gas is present between the support body and the wiring substrate.

14. The light-emitting module according to claim 11, wherein the wiring substrate includes a projection positioned between an overlapping region of the first wiring member that overlaps the first conductor and an overlapping region of the second wiring member that overlaps the second conductor in the view from the side of the second surface.

15. The light-emitting module according to claim 14, wherein the insulating member is in contact with the projection.

16. The light-emitting module according to claim 14, wherein the projection includes a metal member and an insulating layer covering the metal member.

17. The light-emitting module according to claim 16, wherein a thickness of the metal member is between 0.9 and 1.1 times a thickness of the first wiring member.

18. The light-emitting module according to claim 14, wherein
the first electrode and the second electrode are arranged in a first direction, and
a maximum length of the projection in the first direction is less than a maximum length of an interposed portion of the insulating member that is interposed between the light source and the projection.

19. The light-emitting module according to claim 14, wherein
the first electrode and the second electrode are arranged in a first direction, and
a maximum length of the projection in the first direction is greater than a maximum length of an interposed portion of the insulating member that is interposed between the light source and the projection.

20. The light-emitting module according to claim 14, wherein the projection overlaps the first through hole and the second through hole in the view from the side of the second surface.
